(19) United States
(12) Patent Application Publication
(10) Pub. No.: US 2025/0158595 A1
(43) Pub. Date: May 15, 2025

(54) Tuning fork quartz crystal oscillator and resonator

(71) Applicant: Chengdu Timemaker Crystal Technology Co., Ltd., Chengdu (CN)

(72) Inventors: Hui LI, Chengdu (CN); Rongguo CHEN, Chengdu (CN); Zhuzhi YE, Shenzhen (CN)

(73) Assignee: Chengdu Timemaker Crystal Technology Co., Ltd., Chengdu (CN)

(21) Appl. No.: 18/947,009

(22) Filed: Nov. 14, 2024

(30) Foreign Application Priority Data
Nov. 15, 2023 (CN) 202311520065.4

(51) Int. Cl. H03H 9/215

(52) U.S. Cl. CPC H03H 9/215

(57) ABSTRACT

A tuning fork quartz crystal oscillator and a resonator are provided. The tuning fork quartz crystal oscillator includes a quartz crystal oscillator body, where an energy transfer path of the quartz crystal oscillator body is provided with outwardly protruding energy splitters. In the tuning fork quartz crystal oscillator, the outwardly protruding energy splitters are added to a fixed portion of the tuning fork, and the quartz crystal oscillator is packaged and fixed to a ceramic base. This design effectively limits the energy of prongs to the outwardly protruding energy splitters instead of a dispensing position of the fixed portion, avoiding energy transfer to the ceramic base and thus avoiding excessive overall impedance of the device due to vibration leakage.

### CROSS-REFERENCE TO THE RELATED APPLICATIONS

This application is based upon and claims priority to Chinese Patent Application No. 202311520065.4, filed on Nov. 15, 2023, the entire contents of which are incorporated herein by reference.

### TECHNICAL FIELD

The present disclosure relates to the field of quartz crystals, and in particular to a tuning fork quartz crystal oscillator and a resonator.

### BACKGROUND

With the miniaturization of communication terminal electronic products, ultra-thin, especially smart wearable electronic products have strict requirements for circuit installation space, which requires electronic devices to be miniaturized. Among the electronic products, tuning fork quartz crystal resonators used to generate clock signals have gradually reduced their packaging size, which means that the size of tuning fork quartz oscillators is becoming increasingly smaller. Therefore, traditional mechanical processing techniques cannot meet the requirements. In response to this problem, quartz micro-electromechanical system (QMEMS) lithography technology has been applied to the processing of the anisotropic material single crystal SIO₂. At present, the biggest problem with the miniaturization of tuning fork quartz crystal resonators is impedance.

The designed tuning fork chip is fixed to the ceramic base with conductive adhesive, and then the base is vacuum-sealed. The design process generally involves studying the characteristics of the quartz crystal chip, with a focus on the vibration amplitude, frequency, and corresponding vibration impedance of the tuning fork. However, the chip is ultimately fixed to the ceramic base, and the kinetic energy of the vibrating beam is transmitted along the vibrating beam to the area of the fixed portion, resulting in excessive overall impedance of the tuning fork due to vibration leakage.

Overall, the prior art has at least the following technical problem:

The design of quartz tuning fork resonators in the prior art mainly focuses on the design of tuning fork crystal oscillators, ignoring the vibration leakage phenomenon during the packaging process.

### SUMMARY

An objective of the present disclosure is to provide a tuning fork quartz crystal oscillator and a resonator. The present disclosure solves the technical problem that the design of quartz tuning fork resonators in the prior art mainly focuses on the design of tuning fork crystal oscillators, ignoring the vibration leakage phenomenon during the packaging process. The various technical effects achieved by the preferred technical solutions among the many technical solutions provided by the present disclosure are detailed below.

To achieve the above objective, the present disclosure provides the following technical solutions:

The present disclosure provides a tuning fork quartz crystal oscillator, including a quartz crystal oscillator body, where an energy transfer path of the quartz crystal oscillator body is provided with outwardly protruding energy splitters.

Optionally or preferably, the energy splitter provided with at least one pointed structure located away from the quartz crystal oscillator body.

Optionally or preferably, the energy splitter is triangular, rectangular, or trapezoidal in shape; and when the energy splitter is triangular, rectangular, or trapezoidal in shape, one side of the energy splitter is connected to the quartz crystal oscillator body.

Optionally or preferably, two sides of the quartz crystal oscillator body are each provided with at least one energy splitter.

Optionally or preferably, two sides of the quartz crystal oscillator body are each provided with one energy splitter.

Optionally or preferably, the energy splitter is located on a fixed portion of the quartz crystal oscillator body and close to a vibrating beam of the quartz crystal oscillator body.

Optionally or preferably, the energy splitter and the quartz crystal oscillator body are integrated.

The present disclosure provides a resonator, including the above tuning fork quartz crystal oscillator.

According to above technical solutions, embodiments of the present disclosure can achieve at least the following technical effects.

(1) In the tuning fork quartz crystal oscillator provided by the present disclosure, outwardly protruding energy splitters are added to the fixed portion of the quartz crystal oscillator body, and the quartz crystal oscillator is packaged and fixed to the ceramic base. This design effectively limits the energy of the prongs to the outwardly protruding energy splitters instead of the dispensing position of the fixed portion, avoiding energy transfer to the ceramic base and thus avoiding excessive overall impedance of the resonator due to vibration leakage. Compared to the tuning fork crystal oscillator with notches in the prior art, the limited kinetic energy of the resonator of the tuning fork quartz crystal oscillator in the present disclosure is three times that of the resonator in the prior art, indicating a more significant effect. Finite element impedance analysis conducted on the packaged tuning fork quartz crystal oscillator in the present disclosure shows that the impedance of the resonator of the tuning fork quartz crystal oscillator in the present disclosure is lower than that of the resonator of the tuning fork crystal oscillator with notches in the prior art.

(2) The resonator provided by the present disclosure uses the tuning fork quartz crystal oscillator provided by the present disclosure. Outwardly protruding energy splitters are added to the fixed portion of the quartz crystal oscillator body, and the quartz crystal oscillator is packaged and fixed to the ceramic base. This design effectively limits the energy of the prongs to the outwardly protruding energy splitters instead of the dispensing position of the fixed portion, avoiding energy transfer to the ceramic base and thus avoiding excessive overall impedance of the resonator due to vibration leakage.

### BRIEF DESCRIPTION OF THE DRAWINGS

To describe the technical solutions in the embodiments of the present disclosure or in the prior art more clearly, the following briefly describes the drawings required for describing the embodiments or the prior art. Apparently, the drawings in the following description show merely some embodiments of the present disclosure, and those of ordinary skill in the art may still derive other drawings from these drawings without creative efforts.

FIG. 1 is a structural diagram of Embodiment 1 of the present disclosure;

FIG. 2 is a structural diagram of Embodiment 2 of the present disclosure;

FIG. 3 is a structural diagram of Embodiment 3 of the present disclosure;

FIG. 4 is a structural diagram of Embodiment 4 of the present disclosure;

FIG. 5 is a structural diagram of Embodiment 5 of the present disclosure;

FIG. 6 is a structural diagram of Embodiment 6 of the present disclosure;

FIG. 7 is a structural diagram of Embodiment 7 of the present disclosure;

FIG. 8 is a structural diagram of Embodiment 8 of the present disclosure;

FIG. 9 is a structural diagram of Embodiment 9 of the present disclosure;

FIG. 10 is a structural diagram of Embodiment 10 of the present disclosure;

FIG. 11 is a structural diagram of Embodiment 11 of the present disclosure;

FIG. 12 is a structural diagram of Comparative Examples 1 and 2;

FIG. 13 is a calculation model diagram of design and calculation conducted on Comparative Examples 1 and 2 through a finite element method;

FIG. 14 is a gridded model diagram of design and calculation conducted on Comparative Examples 1 and 2 through a finite element method;

FIG. 15 is a kinetic energy diagram of Comparative Example 1 obtained through finite element simulation;

FIG. 16 is a kinetic energy diagram of Comparative Example 2 obtained through finite element simulation;

FIG. 17 is a structural diagram of Comparative Example 3;

FIG. 18 is a time-domain analysis vibration displacement diagram of Comparative Example 3 obtained through finite element simulation;

FIG. 19 is a kinetic energy diagram of Comparative Example 3 obtained through finite element simulation;

FIG. 20 is a gridded model diagram for the design and calculation of Embodiment 3 through a finite element method;

FIG. 21 is a time-domain analysis vibration displacement diagram of Embodiment 3 through finite element simulation;

FIG. 22 is an impedance analysis diagram of Embodiment 3 through finite element simulation;

FIG. 23 is a kinetic energy diagram of Embodiment 3 through finite element simulation;

FIG. 24 is a structural diagram of an SMD2012 quartz crystal oscillator in the prior art;

FIG. 25 is a dimension diagram of Comparative Examples 1 and 2;

FIG. 26 is a dimension diagram of Comparative Example 3; and

FIG. 27 is a dimension diagram of Embodiment 3.

Reference Numerals: 1. quartz crystal oscillator body; 2. energy splitter; 3. pointed structure; and 4. notch.

### DETAILED DESCRIPTION OF THE EMBODIMENTS

To make the objectives, technical solutions, and advantages of the present disclosure more clearly, the technical solutions of the present disclosure will be described in detail below. Apparently, the described embodiments are only a part rather than all of the embodiments of the present disclosure. All other embodiments derived from the embodiments in the present disclosure by a person of ordinary skill in the art without creative efforts shall fall within the protection scope of the present disclosure.

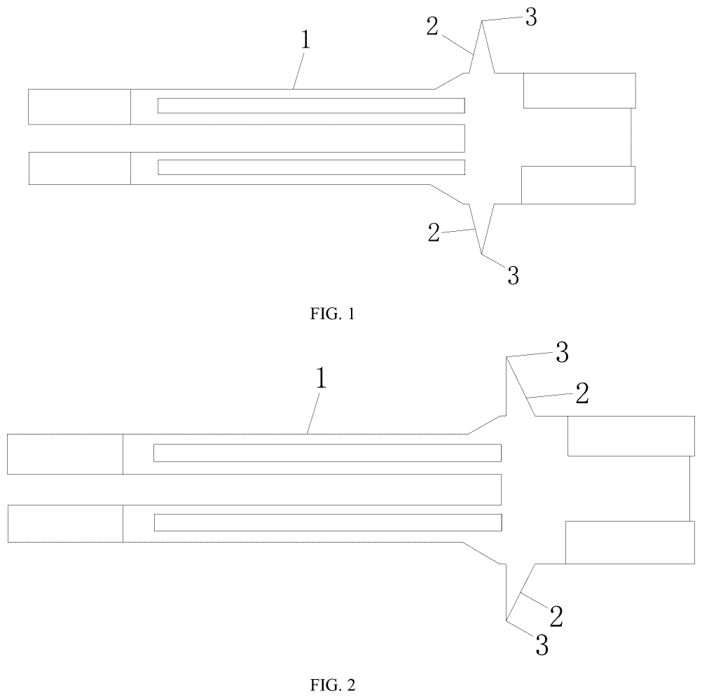

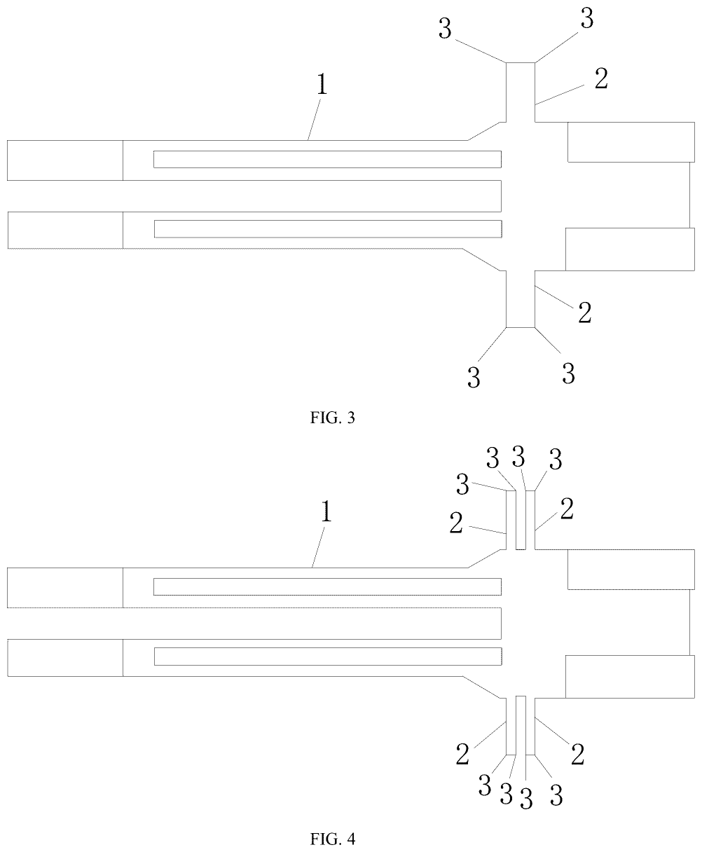

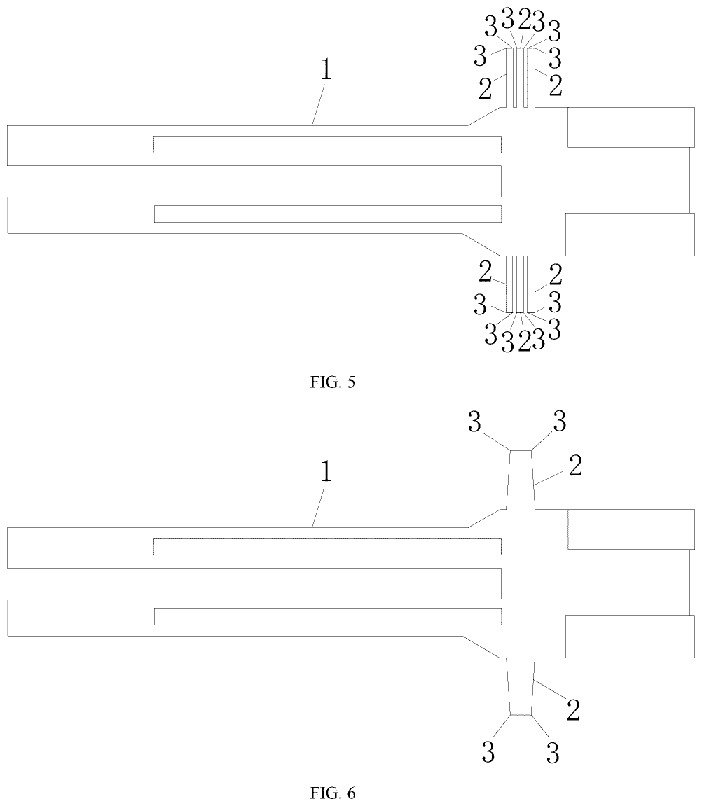

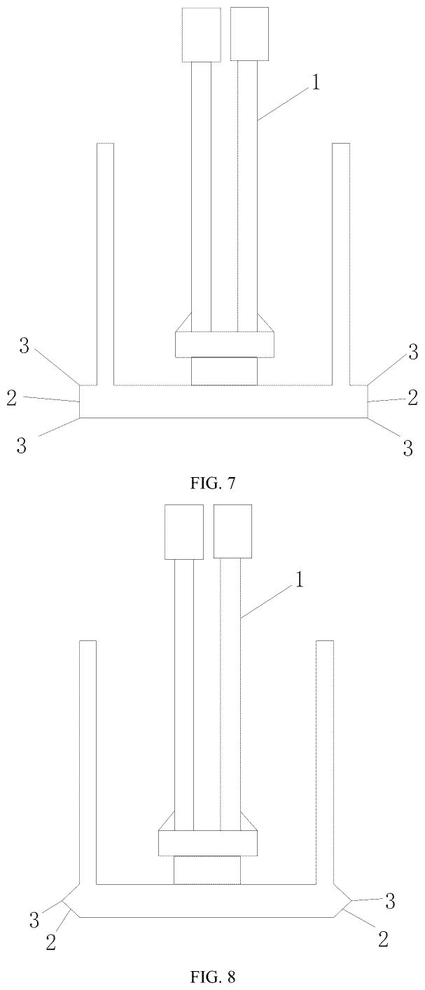

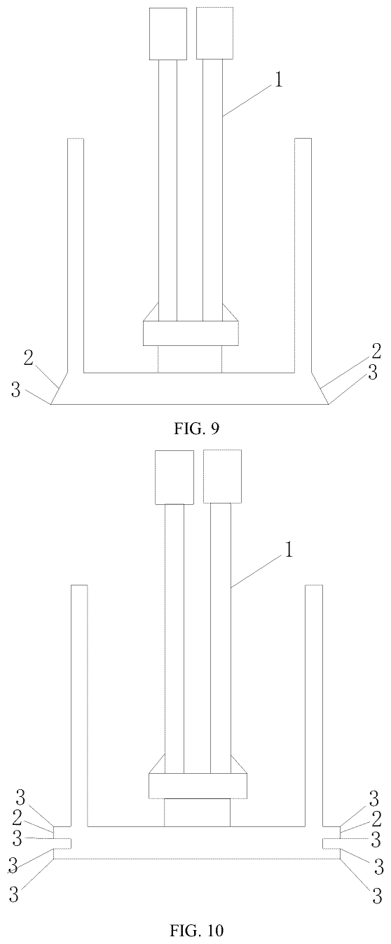

The present disclosure is described below according to FIGS. 1 to 27.

### I. EMBODIMENTS

### Embodiment 1

The present disclosure provides a tuning fork quartz crystal oscillator, including quartz crystal oscillator body 1. An energy transfer path of the quartz crystal oscillator body 1 is provided with outwardly protruding energy splitters 2.

In an optional implementation, the energy splitter 2 is provided with at least one pointed structure 3 located away from the quartz crystal oscillator body 1.

In an optional implementation, the energy splitter 2 is triangular, rectangular, or trapezoidal in shape; and when the energy splitter 2 is triangular, rectangular, or trapezoidal in shape, one side of the energy splitter 2 is connected to the quartz crystal oscillator body 1.

In an optional implementation, two sides of the quartz crystal oscillator body 1 are each provided with at least one energy splitter 2.

In an optional implementation, two sides of the quartz crystal oscillator body 1 are each provided with one energy splitter 2.

In an optional implementation, the energy splitter 2 is located on a fixed portion of the quartz crystal oscillator body 1 and close to a vibrating beam of the quartz crystal oscillator body 1.

In an optional implementation, the energy splitter 2 and the quartz crystal oscillator body 1 are integrated.

In this embodiment, the tuning fork quartz crystal oscillator structurally includes the fixed portion and a pair of vibrating arms symmetrical about a central axis of the fixed portion. An end of the fixed portion away from the vibrating arm is provided with a dispensing platform. The dispensing platform is configured to dispense and fix a tuning fork quartz crystal.

In this embodiment, there are two energy splitters 2 respectively arranged at two sides of the fixed portion of the quartz crystal oscillator body 1, which are isosceles triangles in shape and are each provided with one pointed structure 3.

### Embodiment 2

The difference between this embodiment and Embodiment 1 is that the energy splitter 2 is a right-angled triangle in shape and includes a right-angled side connected to the quartz crystal oscillator body 1.

The other aspects of this embodiment are the same as those of Embodiment 1.

### Embodiment 3

The difference between this embodiment and Embodiment 1 is that the two sides of the fixed portion of the quartz crystal oscillator body 1 are each provided with one energy splitter 2, and the energy splitter 2 is rectangular in shape and provided with two pointed structures 3.

The other aspects of this embodiment are the same as those of Embodiment 1.

### Embodiment 4

The difference between this embodiment and Embodiment 1 is that the two sides of the fixed portion of the quartz crystal oscillator body 1 are each provided with two energy splitters 2, and each of the energy splitters 2 is rectangular in shape and provided with two pointed structures 3.

The other aspects of this embodiment are the same as those of Embodiment 1.

### Embodiment 5

The difference between this embodiment and Embodiment 1 is that the two sides of the fixed portion of the quartz crystal oscillator body 1 are each provided with three energy splitters 2, and each of the energy splitters 2 is rectangular in shape and provided with two pointed structures 3.

The other aspects of this embodiment are the same as those of Embodiment 1.

### Embodiment 6

The difference between this embodiment and Embodiment 1 is that the two sides of the fixed portion of the quartz crystal oscillator body 1 are each provided with one energy splitter 2, and the energy splitter 2 is trapezoidal in shape and provided with two pointed structures 3.

The other aspects of this embodiment are the same as those of Embodiment 1.

### Embodiment 7

The difference between this embodiment and Embodiment 1 is as follows.

In this embodiment, the tuning fork quartz crystal oscillator structurally includes a fixed portion, a pair of vibrating arms symmetrical about a central axis of the fixed portion, and a pair of dispensing arms arranged on the fixed portion, extending along a length direction of the vibrating arms, and parallel to the vibrating arms. The dispensing arms are distributed at two sides of the two vibrating arms. An arm end of the dispensing arm is provided with a dispensing platform, which facilitates the dispensing and fixing of a tuning fork quartz crystal.

In this embodiment, the two sides of the fixed portion of the quartz crystal oscillator body 1 are each provided with one energy splitter 2, and the energy splitter 2 is rectangular in shape and provided with two pointed structures 3.

The other aspects of this embodiment are the same as those of Embodiment 1.

### Embodiment 8

The difference between this embodiment and Embodiment 1 is as follows.

In this embodiment, the tuning fork quartz crystal oscillator structurally includes a fixed portion, a pair of vibrating arms symmetrical about a central axis of the fixed portion, and a pair of dispensing arms arranged on the fixed portion, extending along a length direction of the vibrating arms, and parallel to the vibrating arms. The dispensing arms are distributed at two sides of the two vibrating arms. An arm end of the dispensing arm is provided with a dispensing platform, which facilitates the dispensing and fixing of a tuning fork quartz crystal.

In this embodiment, there are two energy splitters 2 respectively arranged at two sides of the fixed portion of the quartz crystal oscillator body 1, and the energy splitters 2 are isosceles triangles in shape and are each provided with one pointed structure 3.

The other aspects of this embodiment are the same as those of Embodiment 1.

### Embodiment 9

The difference between this embodiment and Embodiment 1 is as follows.

In this embodiment, the tuning fork quartz crystal oscillator structurally includes a fixed portion, a pair of vibrating arms symmetrical about a central axis of the fixed portion, and a pair of dispensing arms arranged on the fixed portion, extending along a length direction of the vibrating arms, and parallel to the vibrating arms. The dispensing arms are distributed at two sides of the two vibrating arms. An arm end of the dispensing arm is provided with a dispensing platform, which facilitates the dispensing and fixing of a tuning fork quartz crystal.

In this embodiment, the two sides of the fixed portion of the quartz crystal oscillator body 1 are each provided with one energy splitter 2. The energy splitter 2 is a right-angled triangle in shape, with a right-angled side connected to the quartz crystal oscillator body 1, and includes one pointed structure 3.

The other aspects of this embodiment are the same as those of Embodiment 1.

### Embodiment 10

The difference between this embodiment and Embodiment 1 is as follows.

In this embodiment, the tuning fork quartz crystal oscillator structurally includes a fixed portion, a pair of vibrating arms symmetrical about a central axis of the fixed portion, and a pair of dispensing arms arranged on the fixed portion, extending along a length direction of the vibrating arms, and parallel to the vibrating arms. The dispensing arms are distributed at two sides of the two vibrating arms. An arm end of the dispensing arm is provided with a dispensing platform, which facilitates the dispensing and fixing of a tuning fork quartz crystal.

In this embodiment, the two sides of the fixed portion of the quartz crystal oscillator body 1 are each provided with two energy splitters 2, and each of the energy splitters 2 is rectangular in shape and provided with two pointed structures 3.

The other aspects of this embodiment are the same as those of Embodiment 1.

### Embodiment 11

The difference between this embodiment and Embodiment 1 is as follows.

In this embodiment, the tuning fork quartz crystal oscillator structurally includes a fixed portion, a pair of vibrating arms symmetrical about a central axis of the fixed portion, and a pair of dispensing arms arranged on the fixed portion, extending along a length direction of the vibrating arms, and parallel to the vibrating arms. The dispensing arms are distributed at two sides of the two vibrating arms. An arm end of the dispensing arm is provided with a dispensing platform, which facilitates the dispensing and fixing of a tuning fork quartz crystal.

In this embodiment, the two sides of the fixed portion of the quartz crystal oscillator body 1 are each provided with one energy splitter 2, and the energy splitter 2 is trapezoidal in shape and provided with two pointed structures 3.

The other aspects of this embodiment are the same as those of Embodiment 1.

### II. COMPARATIVE EXAMPLES

The structural design of SMD3215 tuning fork piezoelectric quartz crystal chips in the prior art is used as Comparative Examples 1, 2, and 3.

The vibration frequency of the tuning fork quartz crystal chip designed in Comparative Examples 1, 2, and 3 is 32.768 KHz.

### Comparative Example 1

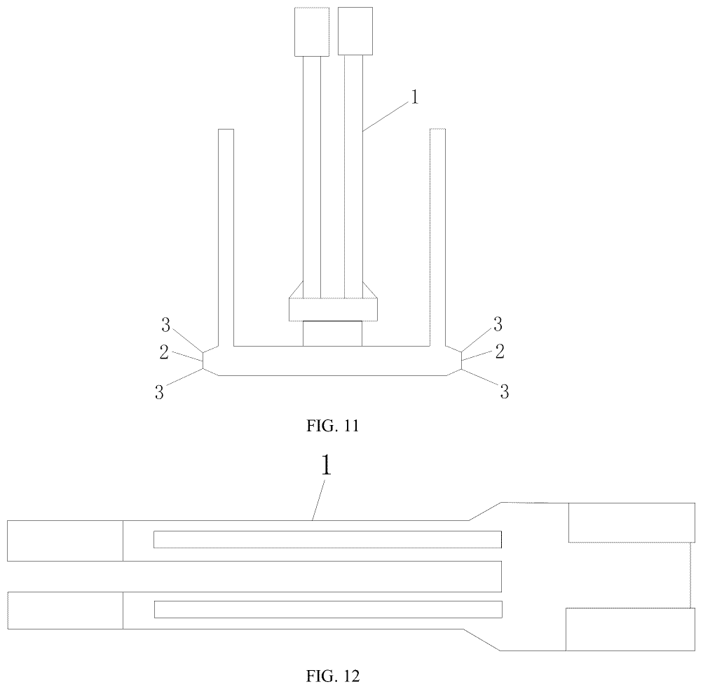

As shown in FIG. 12, the tuning fork quartz crystal structurally includes the fixed portion and a pair of vibrating arms symmetrical about a central axis of the fixed portion. An end of the fixed portion away from the vibrating arm is provided with a dispensing platform.

The dispensing platform is configured to dispense and fix a tuning fork quartz crystal.

### Comparative Example 2

As shown in FIG. 12, the tuning fork quartz crystal structurally includes the fixed portion and a pair of vibrating arms symmetrical about a central axis of the fixed portion. An end of the fixed portion away from the vibrating arm is provided with a dispensing platform. The dispensing platform is configured to dispense and fix a tuning fork quartz crystal.

The biggest difference between Comparative Examples 1 and 2 is the total length of the tuning fork. When the length A of the prongs is the same, the size of the fixed portions of the tuning forks is different. In order to achieve a frequency of 32.768 KHz for the tuning fork, the length and width of the corresponding tuning fork vibrating beams are slightly adjusted. The specific external dimensions of the tuning fork quartz crystals in Comparative Examples 1 and 2 are shown in Table 1 and FIG. 25.

TABLE 1
Design dimensions of SMD3215 tuning fork piezoelectric
quartz crystal chips in Comparative Examples 1 and 2

| Serial | Content of | Comparative | Comparative |
|---|---|---|---|
| Number | Measurement | Example 1 | Example 2 |
| A | Prong length (mm) | 1.797 | 1.797 |
| B | Prong width (mm) | 0.138 | 0.136 |
| C | Total fork length (mm) | 2.332 | 2.342 |
| D | Total fork width (mm) | 0.399 | 0.399 |
| E | Groove width (mm) | 0.069 | 0.069 |
| F | Groove length (mm) | 1.136 | 1.136 |
| G | End length (mm) | 0.520 | 0.524 |
| M | Fork spacing (mm) | 0.045 | 0.045 |
| N | Projection module (45°) | 0.039 | 0.039 |
| depth | Groove depth (mm) | 0.045 | 0.045 |
| thickness | Fork thickness (mm) | 0.110 | 0.110 |

### Comparative Example 3

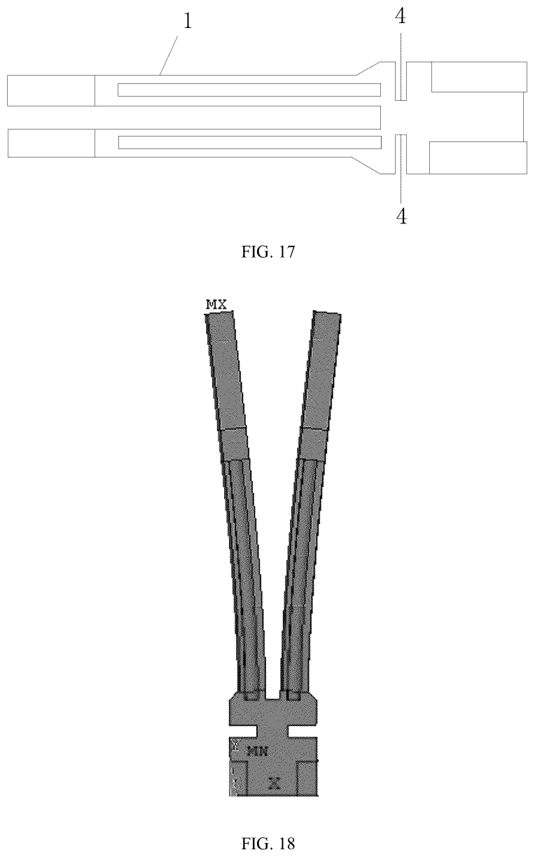

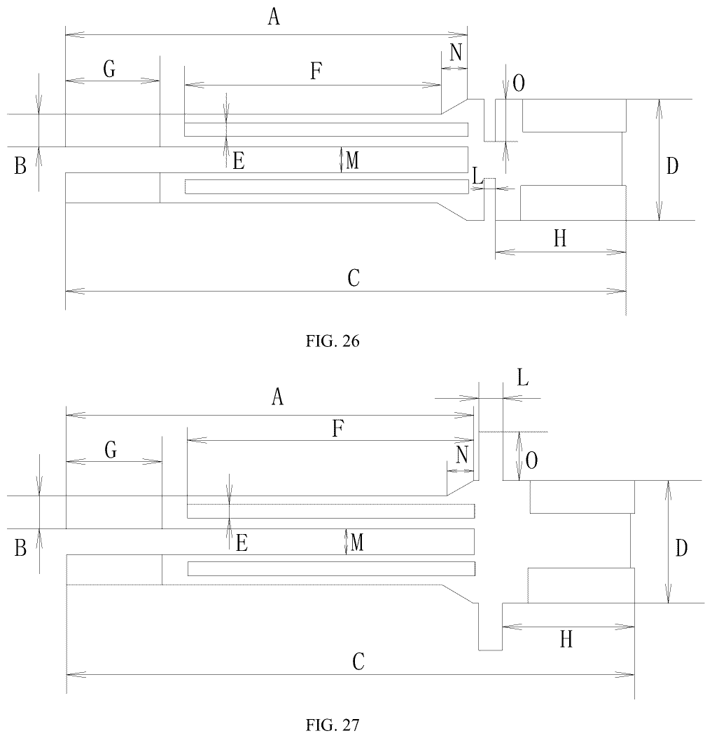

As shown in FIG. 17, the tuning fork quartz crystal structurally includes the fixed portion and a pair of vibrating arms symmetrical about a central axis of the fixed portion. An end of the fixed portion away from the vibrating arm is provided with a dispensing platform. The dispensing platform is configured to dispense and fix a tuning fork quartz crystal. The two sides of the fixed portion are each provided with one notch 4, and the kinetic energy of the prongs is limited at the notches 4. The specific external dimensions of the tuning fork quartz crystal chip in Comparative Example 3 are shown in Table 2 and FIG. 26.

TABLE 2
Specific Dimensions of Comparative Example 3

| Serial | | Comparative |
|---|---|---|
| Number | Content of Measurement | Example 3 |
| A | Prong length (mm) | 1.780 |
| B | Prong width (mm) | 0.136 |
| C | Total fork length (mm) | 2.342 |
| D | Total fork width (mm) | 0.399 |
| E | Groove width (mm) | 0.069 |
| F | Groove length (mm) | 1.136 |
| G | End length (mm) | 0.524 |
| M | Fork spacing (mm) | 0.045 |
| N | Projection module (45°) | 0.039 |
| L | Width of notch 4 (mm) | 0.035 |
| 0 | Length of notch 4 (mm) | 0.120 |
| H | Position of notch 4 (mm) | 0.300 |
| depth | Groove depth (mm) | 0.045 |
| thickness | Fork thickness (mm) | 0.110 |

### III. EXPERIMENTAL EXAMPLE

1. Design and Calculation were Conducted on Comparative Examples 1 and 2 through a finite element method.

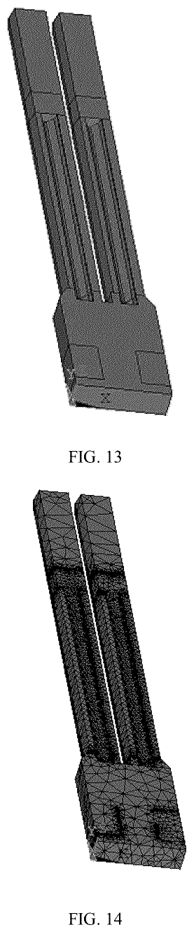

(1) FIG. 13 shows a calculation model, and FIG. 14 shows a gridded model.

(2) The design calculation was conducted through the finite element method, and the results are as follows.

In Comparative Examples 1 and 2, the vibration frequency of the tuning fork quartz crystal chips met the design requirement of 32.768 KHz. In addition, in Comparative Examples 1 and 2, the impedances were 45 KQ and 44.8 KQ, respectively, both of which met requirements.

2. Packaging Experiments were Simultaneously Conducted on the Tuning Fork Quartz Crystal Chips in Comparative Examples 1 and 2 Under the Same Conditions, and the Tuning Fork Resonators were Tested Using a 250 B Plate.

The test results are as follows.

In Comparative Examples 1 and 2, the crystal impedances RR were 86766.62Ω and 43181.10Ω, respectively.

The biggest difference between these two chips was their length. The total length of the chip in Comparative Example 2 was 10 um longer than that in Comparative Example 1, and the length of the tuning prongs in Comparative Example 2 was 17 um shorter than that in Comparative Example 1. This means that the length of the fixed portion of the chip in Comparative Example 2 is 27 um longer than that of the fixed portion in Comparative Example 1.

### 3. The Kinetic Energy of the Chips in Comparative Example 1 and Comparative Example 2 was Compared Through Finite Element Simulation.

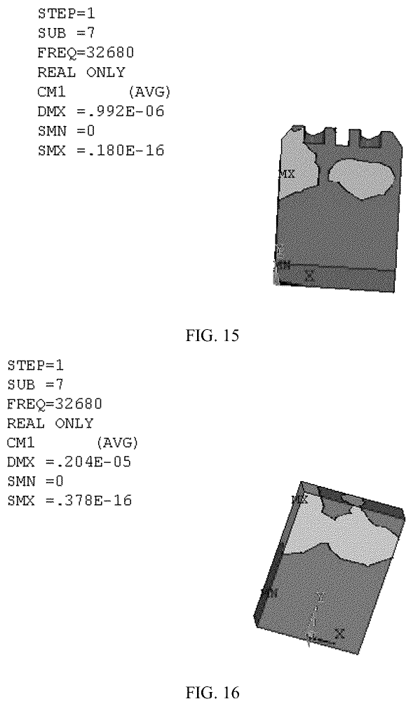

FIG. 15 is a kinetic energy diagram of Comparative Example 1 obtained through finite element simulation.

FIG. 16 is a kinetic energy diagram of Comparative Example 2 obtained through finite element simulation.

The simulation results show that the kinetic energy transmitted from the tuning fork to the fixed portion in Comparative Example 1 was three times that in Comparative Example 2. Therefore, the size of the fixed portion often affects the vibration impedance of the entire device. Limiting the kinetic energy of the tuning fork's prongs to a local area rather than transferring too much to the fixed portion can help avoid energy transfer between the tuning fork and the base, known as the vibration leakage phenomenon. Therefore, it is necessary to increase the design size of the fixed portion during the design process. However, due to the problem of the packaging size, the size of the fixed portion is also limited.

### 4. Calculation was Conducted for Comparative Example 3 Through the Finite Element Simulation Method.

Calculation was conducted for Comparative Example 3 through the finite element simulation method, and the kinetic energy transfer in this comparative example was compared with that in Comparative Examples 1 and 2.

FIG. 18 is a time-domain analysis vibration displacement diagram of Comparative Example 3 obtained through finite element simulation.

FIG. 19 is a kinetic energy diagram of Comparative Example 3 obtained through finite element simulation.

Through simulation, it can be clearly observed that in Comparative Example 3, the kinetic energy of the prongs of the tuning fork was effectively isolated to a part above the notches 4 before the notch 4 structure limited the kinetic energy of the prongs of the tuning fork to the notches 4. However, compared to the structure without the notches 4, although the kinetic energy was isolated, the magnitude of the kinetic energy transmitted by the prongs was much greater than that transmitted by the structure without the notches 4. Therefore, this structural design relies on a “blocking” approach to solve the problem.

### 5. Corresponding Finite Element Modeling was Conducted on Embodiment 3 Based on the Dimensions in Table 3 and FIG. 27.

TABLE 3
Specific Dimensions of Embodiment 3

| Serial | | |
|---|---|---|
| Number | Content of Measurement | Embodiment 3 |
| A | Prong length (mm) | 1.780 |
| B | Prong width (mm) | 0.136 |
| C | Total fork length (mm) | 2.342 |
| D | Total fork width (mm) | 0.399 |
| E | Groove width (mm) | 0.069 |
| F | Groove length (mm) | 1.136 |
| G | End length (mm) | 0.524 |
| M | Fork spacing (mm) | 0.045 |
| N | Projection module (45°) | 0.039 |
| L | Width of energy splitter 2 (mm) | 0.093 |
| 0 | Length of energy splitter 2 (mm) | 0.155 |
| H | Position of energy splitter 2 (mm) | 0.410 |
| depth | Groove depth (mm) | 0.045 |
| thickness | Fork thickness (mm) | 0.110 |

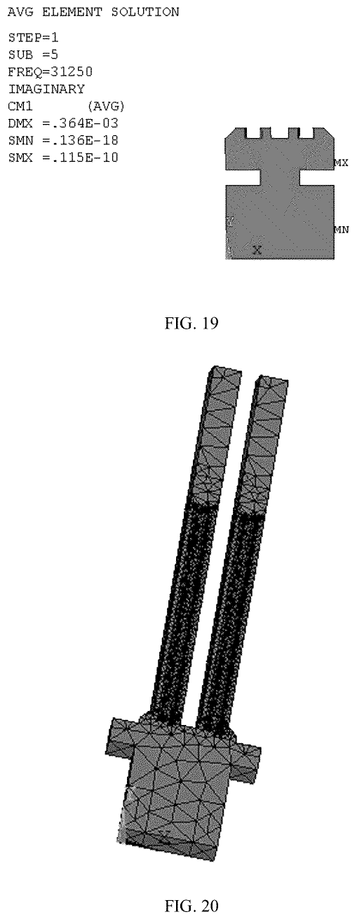

FIG. 20 is a gridded model diagram for the design and calculation of Embodiment 3 through the finite element method according to the dimensions in Table 2.

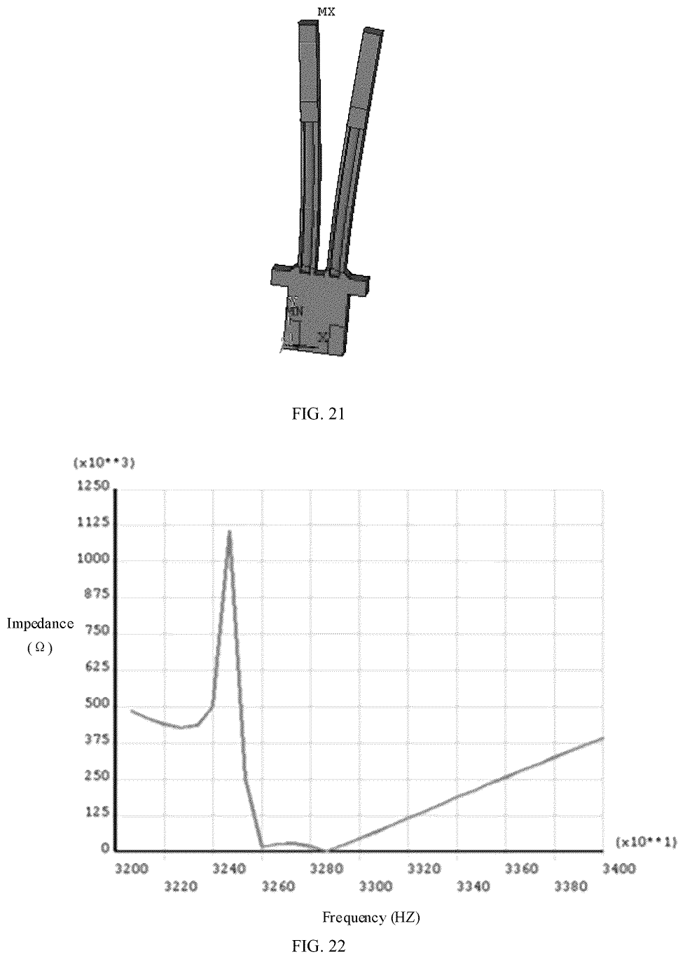

FIG. 21 is a time-domain analysis vibration displacement diagram of Embodiment 3 through finite element simulation according to the dimensions in Table 2.

FIG. 22 is an impedance analysis diagram of Embodiment 3 through finite element simulation according to the dimensions in Table 2.

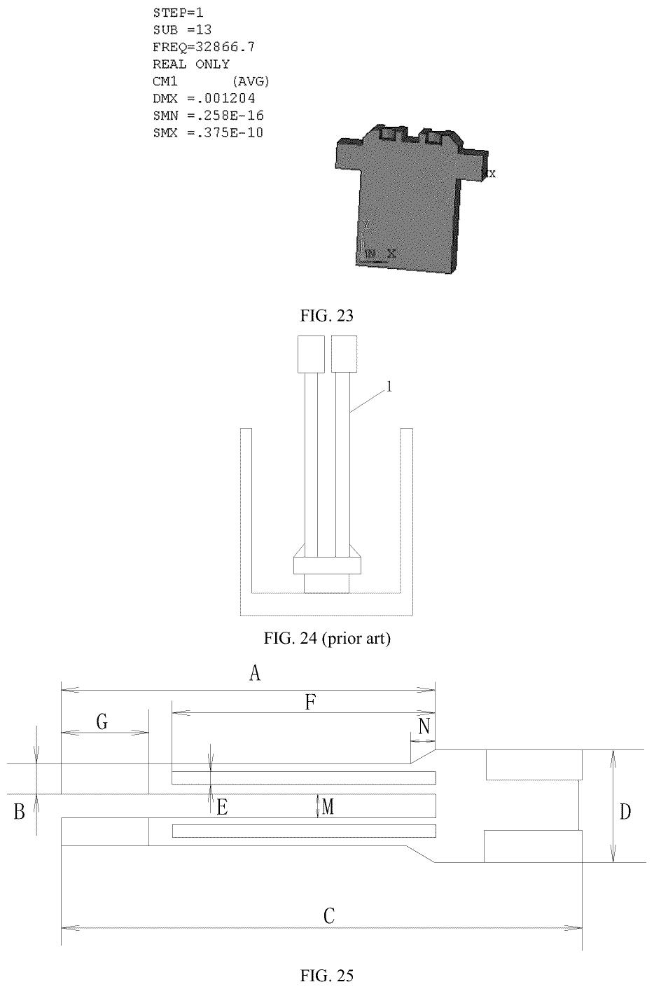

FIG. 23 is a kinetic energy diagram of Embodiment 3 through finite element simulation according to the dimensions in Table 2.

The above analysis shows that adding the energy splitters 2 to the fixed portion of the tuning fork effectively limited the kinetic energy of the prongs to the part of the energy splitters 2 rather than to the position of the dispensing platform, thereby avoiding the transfer of the kinetic energy to the ceramic base and causing excessive overall impedance of the device. Compared to the tuning fork crystal oscillator with notches 4 in Comparative Example 3, the limited kinetic energy of the resonator of the tuning fork quartz crystal oscillator in Embodiment 3 is three times that of the resonator in Comparative Example 3, indicating a more significant effect. In addition, the impedance obtained through finite element analysis of the tuning fork chip in Embodiment 3 was 38 KQ. In contrast, the impedance in Embodiment 3 is lower than the impedance of 42 KQ in Comparative Example 3.

### 6. Finite Element Simulation Modeling was Conducted for Comparative Examples 1 to 3 and Embodiments 1 to 11.

The limited kinetic energy of the tuning fork crystal resonator and the impedance of the chip are shown in Table 4.

TABLE 4
Experimental results of finite element modeling
for Comparative Examples and Embodiments

| | Limited kinetic | | |
|---|---|---|---|
| | energy of resonator | | |
| | Minimum | Maximum | Impedance of |
| | kinetic | kinetic | tuning fork |
| | energy (SMN) | energy (SMX) | chip, KΩ |
| Comparative | 0 | 0.180e−16 | 876.6 |
| Example 1 | | | |
| Comparative | 0 | 0.378e−16 | 43.1 |
| Example 2 | | | |
| Comparative | 0.136e−18 | 0.115e−10 | 42 |
| Example 3 | | | |
| Embodiment 1 | 0.214e−16 | 0.238e−10 | 39 |
| Embodiment 2 | 0.102e−16 | 0.125e−10 | 40 |
| Embodiment 3 | 0.258e−16 | 0.375e−10 | 38 |
| Embodiment 4 | 0.485e−16 | 0.502e−10 | 36 |
| Embodiment 5 | 0.835e−16 | 0.869e−10 | 34 |
| Embodiment 6 | 0.241e−16 | 0.365e−10 | 38.2 |
| Embodiment 7 | 0.368e−16 | 0.458e−10 | 37.8 |
| Embodiment 8 | 0.126e−16 | 0.283e−10 | 39 |
| Embodiment 9 | 0.118e−16 | 0.296e−10 | 39 |
| Embodiment | 0.325e−16 | 0.409e−10 | 36.3 |
| 10 | | | |
| Embodiment | 0.253e−16 | 0.306e−10 | 38 |
| 11 | | | |

According to Table 4, the limited kinetic energy of the resonator of the tuning fork quartz crystal oscillator in Embodiments 1 to 11 of the present disclosure is much greater than that of the resonator of the tuning fork quartz crystal oscillator in Comparative Examples 1 to 3. Moreover, the impedance analysis of the tuning fork quartz crystal oscillator in Embodiments 1 to 11 and Comparative Examples 1 to 3 through the finite element method shows that the impedance of the tuning fork quartz crystal oscillator in Embodiments 1 to 11 is lower. In Embodiments 1 to 11 of the present disclosure, outwardly protruding energy splitters 2 are added to the fixed portion of the quartz crystal oscillator body 1, and the quartz crystal oscillator is packaged and fixed to the ceramic base. This design effectively limits the energy of the prongs to the outwardly protruding energy splitters 2 instead of the dispensing position of the fixed portion, avoiding energy transfer to the ceramic base and thus avoiding excessive overall impedance of the device due to vibration leakage.

The above are merely specific implementations of the present disclosure, and the protection scope of the present disclosure is not limited thereto. Any modification or replacement easily conceived by those skilled in the art within the technical scope of the present disclosure should fall within the protection scope of the present disclosure.

What is claimed is:

1. A tuning fork quartz crystal oscillator, comprising a quartz crystal oscillator body, wherein an energy transfer path of the quartz crystal oscillator body is provided with outwardly protruding energy splitters.

2. The tuning fork quartz crystal oscillator according to claim 1, wherein the energy splitter is provided with at least one pointed structure located away from the quartz crystal oscillator body.

3. The tuning fork quartz crystal oscillator according to claim 1, wherein the energy splitter is triangular, rectangular, or trapezoidal in shape; and when the energy splitter is triangular, rectangular, or trapezoidal in shape, one side of the energy splitter is connected to the quartz crystal oscillator body.

4. The tuning fork quartz crystal oscillator according to claim 1, wherein two sides of the quartz crystal oscillator body are each provided with at least one energy splitter.

5. The tuning fork quartz crystal oscillator according to claim 1, wherein two sides of the quartz crystal oscillator body are each provided with one energy splitter.

6. The tuning fork quartz crystal oscillator according to claim 1, wherein the energy splitter is located on a fixed portion of the quartz crystal oscillator body and adjacent to a vibrating beam of the quartz crystal oscillator body.

7. The tuning fork quartz crystal oscillator according to claim 1, wherein the energy splitter and the quartz crystal oscillator body are integrated.

8. A resonator, comprising the tuning fork quartz crystal oscillator according to claim 1.

9. The tuning fork quartz crystal oscillator according to claim 2, wherein the energy splitter and the quartz crystal oscillator body are integrated.

10. The tuning fork quartz crystal oscillator according to claim 3, wherein the energy splitter and the quartz crystal oscillator body are integrated.

11. The tuning fork quartz crystal oscillator according to claim 4, wherein the energy splitter and the quartz crystal oscillator body are integrated.

12. The tuning fork quartz crystal oscillator according to claim 5, wherein the energy splitter and the quartz crystal oscillator body are integrated.

13. The tuning fork quartz crystal oscillator according to claim 6, wherein the energy splitter and the quartz crystal oscillator body are integrated.

14. The resonator according to claim 8, wherein in the tuning fork quartz crystal oscillator, the energy splitter is provided with at least one pointed structure located away from the quartz crystal oscillator body.

15. The resonator according to claim 8, wherein in the tuning fork quartz crystal oscillator, the energy splitter is triangular, rectangular, or trapezoidal in shape; and when the energy splitter is triangular, rectangular, or trapezoidal in shape, one side of the energy splitter is connected to the quartz crystal oscillator body.

16. The resonator according to claim 8, wherein in the tuning fork quartz crystal oscillator, two sides of the quartz crystal oscillator body are each provided with at least one energy splitter.

17. The resonator according to claim 8, wherein in the tuning fork quartz crystal oscillator, two sides of the quartz crystal oscillator body are each provided with one energy splitter.

18. The resonator according to claim 8, wherein in the tuning fork quartz crystal oscillator, the energy splitter is located on a fixed portion of the quartz crystal oscillator body and adjacent to a vibrating beam of the quartz crystal oscillator body.

19. The resonator according to claim 8, wherein in the tuning fork quartz crystal oscillator, the energy splitter and the quartz crystal oscillator body are integrated.

20. The resonator according to claim 14, wherein in the tuning fork quartz crystal oscillator, the energy splitter and the quartz crystal oscillator body are integrated.
